(19) United States
(12) Patent Application Publication
(10) Pub. No.: US 2022/0177717 A1
(43) Pub. Date: Jun. 9, 2022

(54) CONTACT STRUCTURE, ELECTRONIC DEVICE, AND METHOD OF MANUFACTURING CONTACT STRUCTURE

(71) Applicant: TPK Advanced Solutions Inc., Xiamen (CN)

(72) Inventors: Zhi-Qiang Lin, Haikou City (CN); Yi-Min Jiang, Xiamen City (CN); Shen-Jie Chen, Zhangping City (CN); Ting-Ting Li, Yuxi City (CN); Xi-Zhao Wang, Dengzhou City (CN); Li-Wei Mu, Guyuan City (CN); Shan-Yu Wu, New Taipei City (TW); Chih-Min Chen, Taichung City (TW); Chao-Hui Kuo, Taipei City (TW)

(21) Appl. No.: 17/116,135

(22) Filed: Dec. 9, 2020

(51) Int. Cl. C09D 7/63; G06F 3/041; G03F 7/16; C23C 30/00

(52) U.S. Cl. CPC C09D 7/63; G06F 3/041; G06F 2203/04103; C23C 30/00; G03F 7/16

(57) ABSTRACT

A contact structure is provided, which includes a substrate, a copper layer, an organic composite protective layer, and a nanosilver layer. The copper layer is disposed over the substrate. The organic composite protective layer is disposed over the copper layer to avoid oxidation of the copper layer, in which the organic composite protective layer forms a monomolecular adsorption layer over a surface of the copper layer. The nanosilver layer is disposed over the organic composite protective layer. A method of manufacturing a contact structure is also provided.

### BACKGROUND

### Field of Disclosure

The present disclosure relates to a contact structure, an electronic device, and manufacturing methods thereof, and particularly to a contact structure having a copper layer and a nanosilver layer stacked with each other, an electronic device, and manufacturing methods thereof.

### Description of Related Art

In some electronic devices (e.g., touch panels), at a contact area at an intersection of a touch electrode and a transmission line, the transmission line is mostly a copper material layer, and the touch electrode is a nanosilver material layer. However, when a device that includes this contact area is manufactured, during a photo process, oxidation-reduction reaction will occur due to a potential difference between copper and silver in a stripping liquid (e.g., Tetramethylammonium hydroxide (TMAH) solution), causing oxidation and discoloration of the copper material layer.

FIG. 1A is a schematic diagram of a conventional device 10 including a contact area 20 before being treated with a stripping liquid in a patterning process. The device 10 includes a substrate 12, a copper layer 14 over the substrate 12, and a nanosilver layer 16 over the substrate 12 and partially covering the copper layer 14. FIG. 1B is a schematic diagram of the device of FIG. 1A after treatment with the stripping liquid of the photo process, in which the copper layer 14′ in the contact area 20 is discolored. FIG. 10 is a partial top view image of the contact area 20 of FIG. 1B, which shows the boundary where the nanosilver layer 16 covers the copper layer 14′. As evident from the image, in the portion of the copper layer 14′ covered by the nanosilver layer 16, the color of the copper layer 14′ is changed to a darker color, resulting in a user more easily seeing the copper layer 14′.

Since the oxidation and discoloration of the copper layer will affect the appearance of the product, in view of this problem, the existing contact structure having the nanosilver layer and the copper layer needs to be improved.

### SUMMARY

One of the purposes of the embodiments of the present disclosure is to provide a contact structure that avoids oxidation and discoloration of copper in a stacked structure having a copper layer and a nanosilver layer during a subsequent photo process by providing a protective layer over the copper layer.

One of the purposes of the embodiments of the present disclosure is to provide a protective layer, which has a good match ability with a nanosilver layer.

Some embodiments of the present disclosure provide a contact structure, which includes: a substrate, a copper layer, an organic composite protective layer, and a nanosilver layer. The copper layer is disposed over the substrate. The organic composite protective layer is disposed over the copper layer to mitigate oxidation of the copper layer, in which the organic composite protective layer forms a monomolecular adsorption layer over a surface of the copper layer. The nanosilver layer is disposed over the organic composite protective layer.

In some embodiments, the organic composite protective layer includes a composition having a nitrogen-containing heterocyclic compound, or a composition of a cross-linking agent and a coupling agent.

In some embodiments, the organic composite protective layer includes benzotriazole and imidazoline.

In some embodiments, a weight ratio of the benzotriazole to the imidazoline is in a range of from 1:100 to 100:1.

In some embodiments, a weight ratio of the benzotriazole to the imidazoline is in a range of from 1:1 to 1:3.

In some embodiments, the organic composite protective layer includes: a cross-linking agent and a chelating agent. The cross-linking agent is a silane cross-linking agent, a titanate cross-linking agent, a multifunctional cross-linking agent, or a combination thereof. The chelating agent is an organic chelating agent, a metal chelating agent, or a combination thereof.

In some embodiments, a weight ratio of the cross-linking agent to the chelating agent is in a range of from 1:100 to 100:1.

In some embodiments, the cross-linking agent is hexamethyldisiloxane, and the chelating agent is ethylenediamine.

In some embodiments, a weight ratio of the hexamethyldisiloxane to the ethylenediamine is in a range of from 3:1 to 6:1.

In some embodiments, the cross-linking agent is triisostearoyl isopropoxy titanate (TTS), and the chelating agent is ethylenediaminetetraacetic acid (EDTA).

In some embodiments, the organic composite protective layer has a thickness in a range of from about 50 nm to about 100 nm.

In some embodiments, the Δa* value measured after the contact structure is immersed in tetramethylammonium hydroxide is not greater than 0.7.

Some embodiments of the present disclosure provide an electronic device, which includes a contact structure formed by a copper layer and a nanosilver layer, in which an organic composite protective layer is disposed between the copper layer and the nanosilver layer.

In some embodiments, in the contact structure of the electronic device, at least one side of the copper layer, at least one side of the organic composite protective layer, and at least one side of the nanosilver layer are aligned with each other.

Some embodiments of the present disclosure provides a method of manufacturing a contact structure, which includes: providing a copper layer disposed over a substrate; coating a protective layer solution on the copper layer, the protective layer solution including an organic protective composition, organic alcohols, and water; forming an organic composite protective layer from the protective layer solution; and disposing a nanosilver layer over the organic composite protective layer.

In some embodiments, the organic protective composition includes a composition having a nitrogen-containing heterocyclic compound, or a composition of a cross-linking agent and a coupling agent.

In some embodiments, the organic protective composition includes benzotriazole and imidazoline. The benzotriazole is present in an amount of from about 0.1 to about 10 percent by weight of the protective layer solution, and the imidazoline is present in an amount of from about 0.1 to about 10 percent by weight of the protective layer solution.

In some embodiments, the organic protective composition includes: a cross-linking agent and a chelating agent. The cross-linking agent includes a silane cross-linking agent, a titanate cross-linking agent, a multifunctional cross-linking agent, or a combination thereof. A ratio of the cross-linking agent in the protective layer solution is in a range of from about 0.05 to about 20 percent by weight. The chelating agent includes an organic chelating agent, a metal chelating agent, or a combination thereof. A ratio of the chelating agent in the protective layer solution is in a range of from about 0.05 to about 20 percent by weight.

In some embodiments, the method further includes: etching the copper layer, the organic composite protective layer, and the nanosilver layer during a patterning process.

In some embodiments, after the patterning process, one side of the copper layer, one side of the organic composite protective layer, and one side of the nanosilver layer are aligned with each other.

### BRIEF DESCRIPTION OF THE DRAWINGS

Various aspects of the present disclosure will be most easily understood when the following detailed description is read in conjunction with the accompanying drawings. It should be noted that according to industry standard operating procedures, various characteristic structures may not be drawn to scale. In fact, for clarity of discussion, the size of various characteristic structures may be arbitrarily increased or decreased.

FIG. 1A is a schematic diagram of a conventional device including a contact structure before being treated with a stripping liquid of a photo process.

FIG. 1B is a schematic diagram of a conventional device including a contact structure after treatment with a stripping liquid of a photo process.

FIG. 10 is a partial top view image of an area 20 of FIG. 1B.

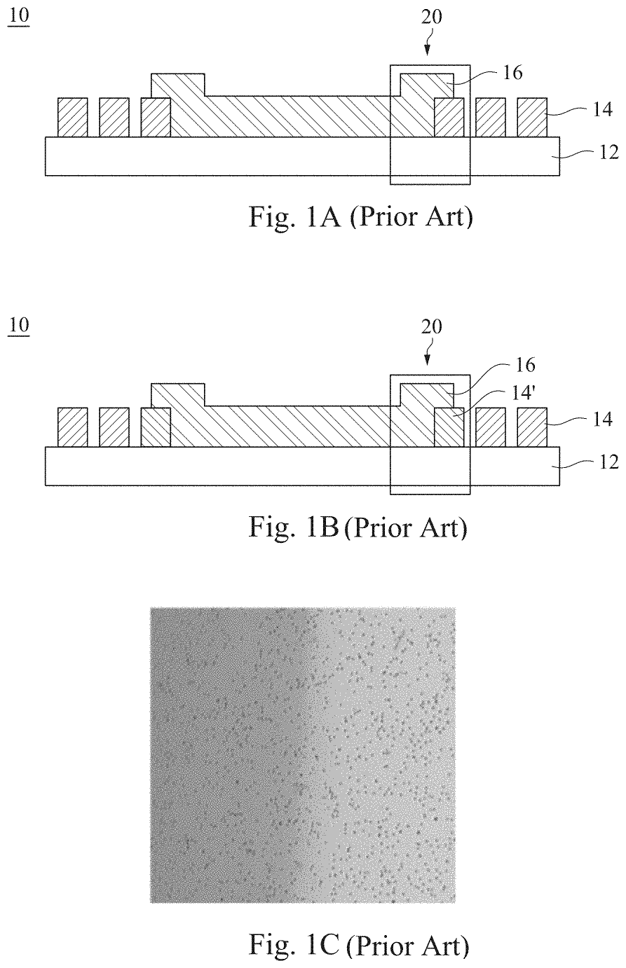

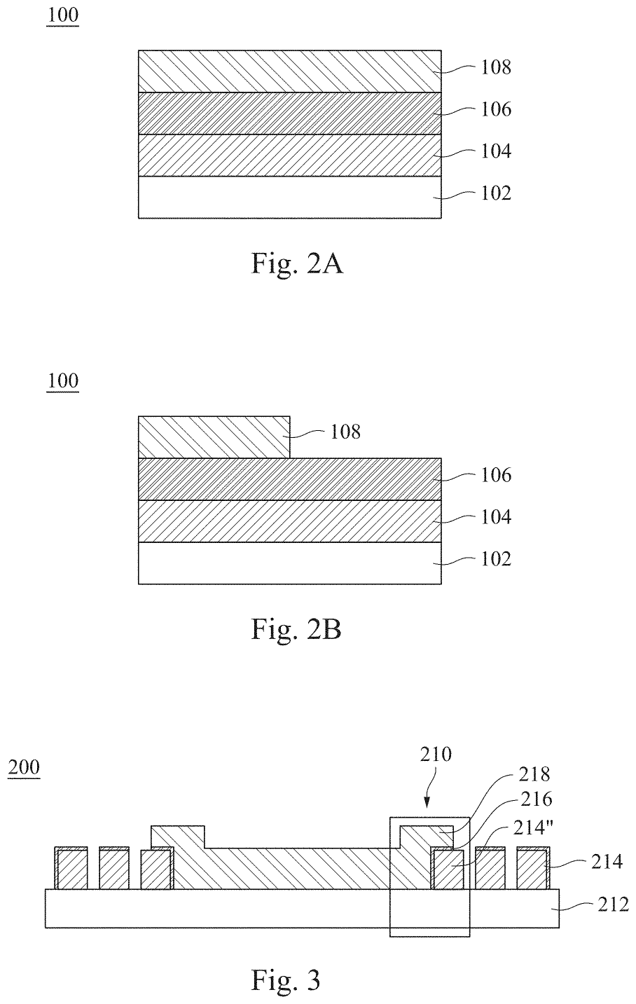

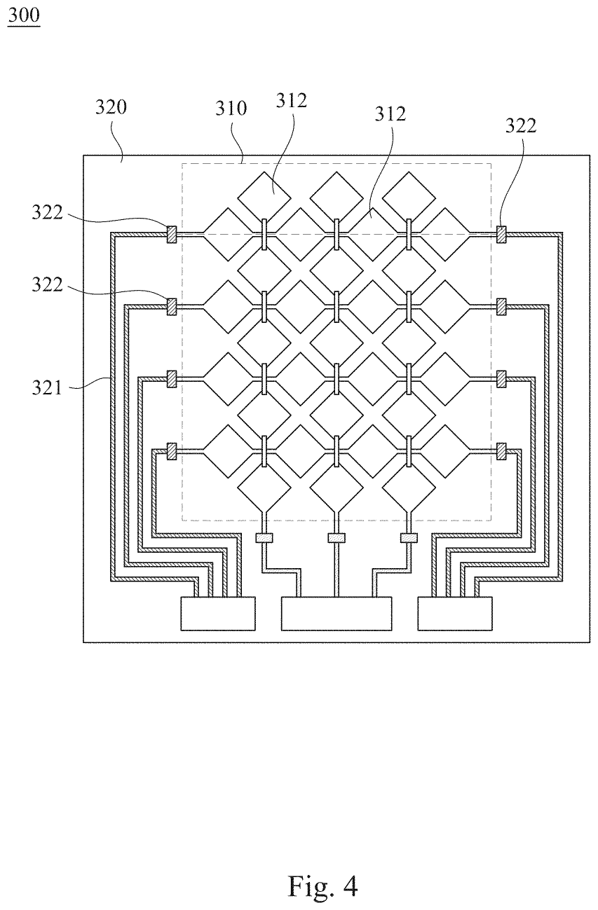

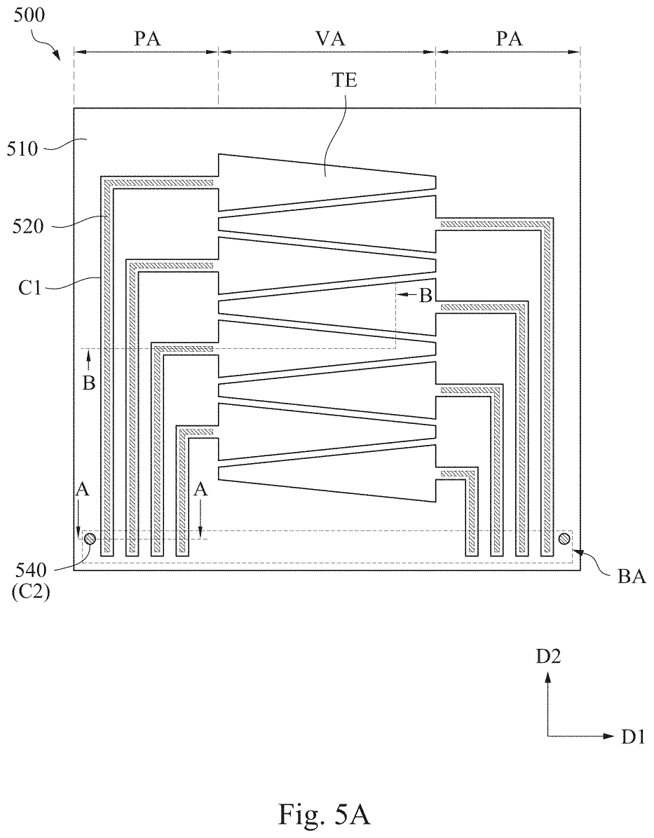

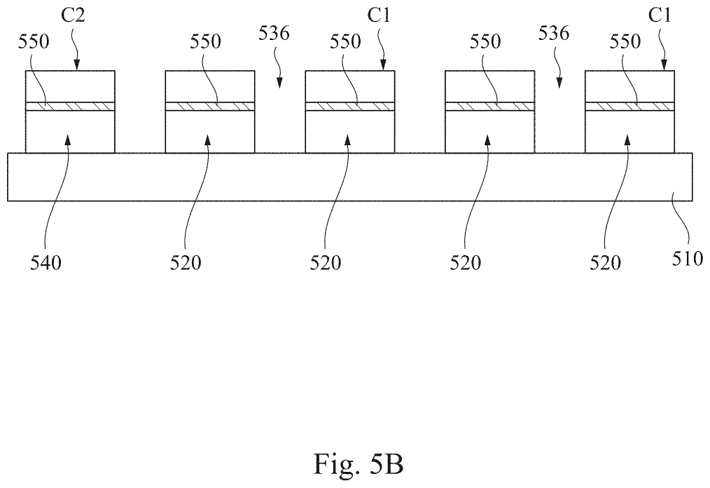

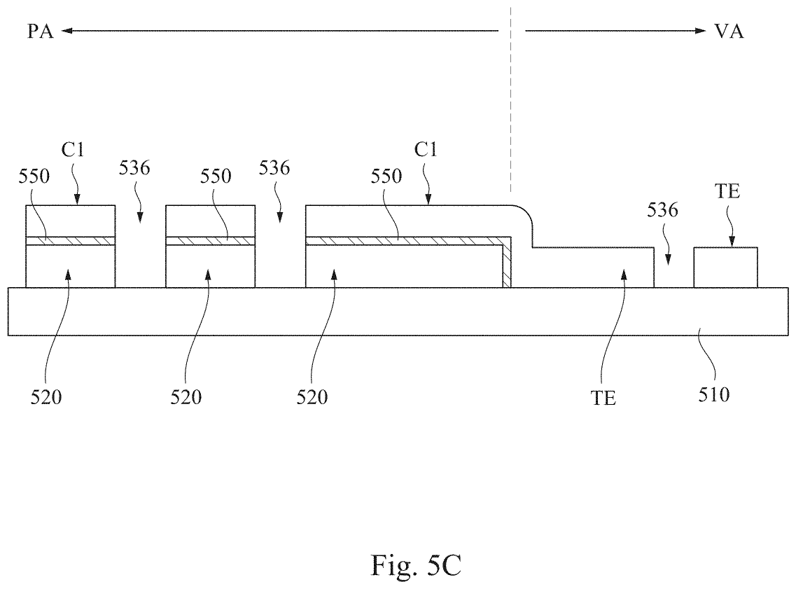

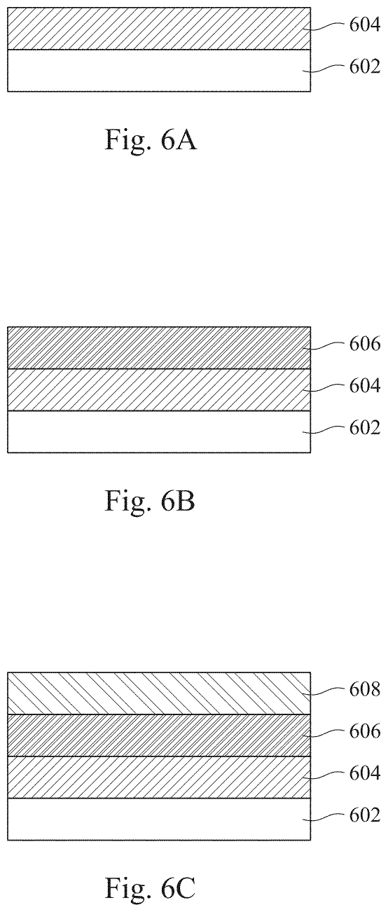

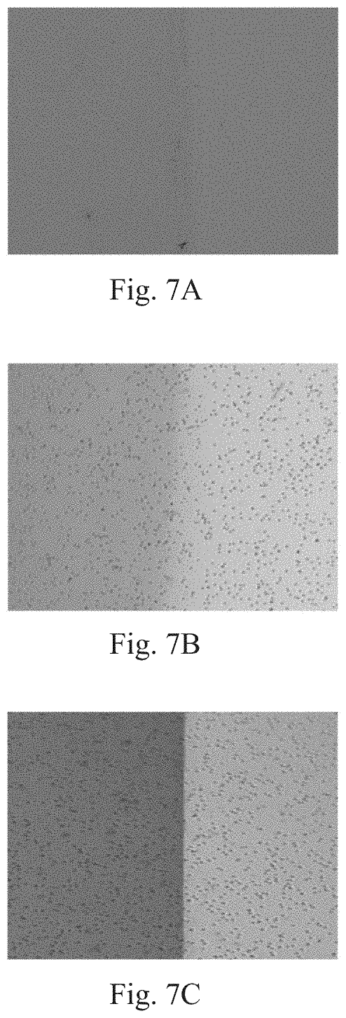

FIG. 2A is a schematic cross-sectional view of a contact structure according to some embodiments of the present disclosure.

FIG. 2B is a schematic cross-sectional view of a contact structure according to some embodiments of the present disclosure.

FIG. 3 is a schematic cross-sectional view of a device according to some embodiments of the present disclosure.

FIG. 4 is a top view of a touch panel according to some embodiments of the present disclosure.

FIG. 5A is a schematic top view of a touch panel according to some embodiments of the present disclosure.

FIG. 5B is a schematic cross-sectional view taken along the line A-A of FIG. 5A.

FIG. 5C is a schematic cross-sectional view taken along the line B-B of FIG. 5B.

FIGS. 6A to 6C are schematic cross-sectional views illustrating various steps of a method of manufacturing a contact structure according to an embodiment of the present disclosure.

FIGS. 7A to 7C are top view images of a structure of Comparative Example 1 of the present disclosure after immersion in a stripping liquid.

FIGS. 8A to 8C are top view images of a structure of Comparative Example 2 of the present disclosure after immersion in a stripping liquid.

FIGS. 9A to 9C are top view images of a structure of Experimental Example 1 of the present disclosure after immersion in a stripping liquid.

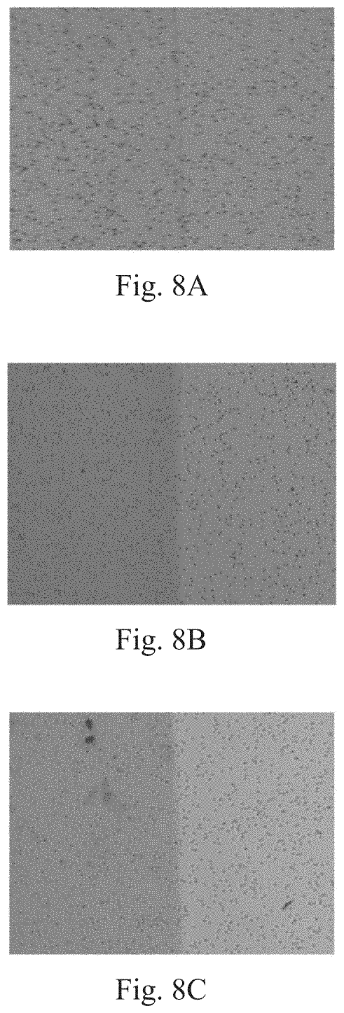

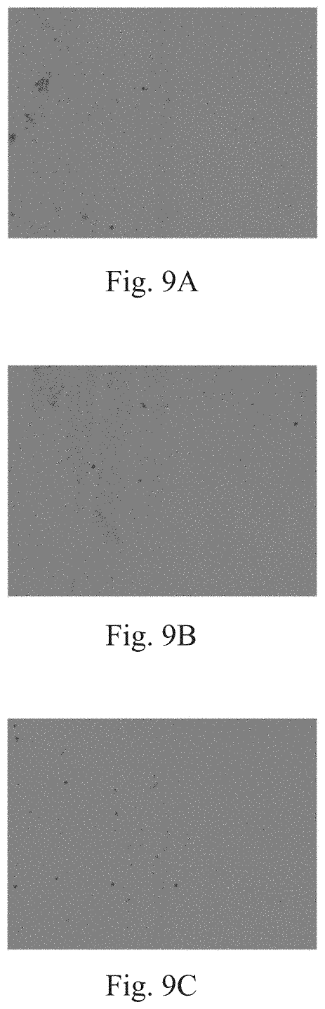

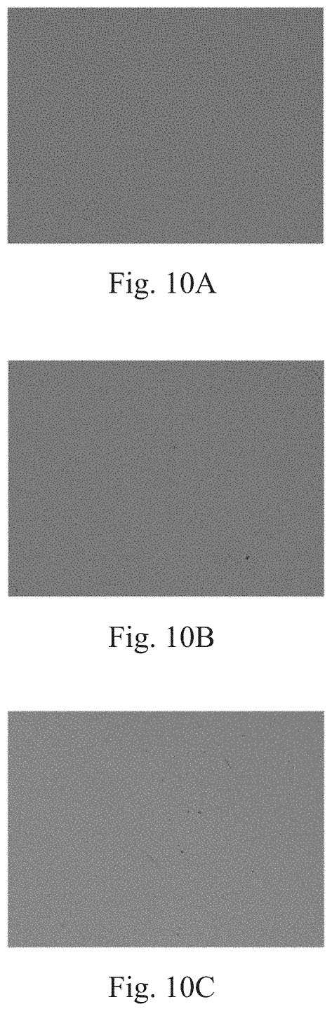

FIGS. 10A to 10C are top view images of a structure of Experimental Example 2 of the present disclosure after immersion in a stripping liquid.

### DETAILED DESCRIPTION

The following disclosure provides different embodiments or examples to achieve different features of the provided subject matter. Specific examples of components and configurations are described below to simplify the present disclosure. Of course, these are only examples and are not intended to limit the present disclosure. For example, in the following description, a first feature is formed to be higher than a second feature, which may include an embodiment in which the first and second features are formed in direct contact, and may also include additional features provided between the first and second features. Therefore, there is an embodiment that the first and second features are not in direct contact. In addition, the present disclosure may repeat numbers and/or letters in each embodiment. Such repetition does not imply a relationship between the various embodiments and/or configurations discussed.

In addition, in order to facilitate the description of the relationship between one element or feature and another element or feature, as shown in the figures, spatially relative terms may be used here, such as “below”, “beneath”, “lower”, “on”, “over”, “higher”, and similar terms. In addition to the directions shown in the figures, spatially relative terms are intended to cover different directions of the device in use or operation. The device can have other directions (rotation by 90 degrees or other directions), and the spatially relative terms used here can also be interpreted accordingly.

Please refer to FIG. 2A, which shows a contact structure 100 according to some embodiments of the present disclosure. The contact structure includes a substrate 102, a copper layer 104, an organic composite protective layer 106, and a nanosilver layer 108 (also referred to as a “silver nanowire layer”). The copper layer 104 is disposed over the substrate 102, the organic composite protective layer 106 is disposed over the copper layer 104, and the nanosilver layer 108 is disposed over the organic composite protective layer 106. In other words, the organic composite protective layer 106 is disposed between the copper layer 104 and the nanosilver layer 108. The organic composite protective layer 106 does not affect the electrical connection between the copper layer 104 and the nanosilver layer 108 but prevents the copper layer 104 from discoloration during a subsequent photo process by suppressing copper oxidation during a stripping liquid (e.g., Tetramethylammonium hydroxide) treatment.

In other embodiments, as shown in FIG. 2B, the nanosilver layer 108 partially covers the copper layer 104. In other words, a portion of the copper layer 104 is indirectly in contact with the nanosilver layer 108 through the organic composite protective layer 106, and there is another portion of the copper layer 104 that has no overlying nanosilver layer (i.e., another portion of the copper layer 104 that is not overlaid by the nanosilver layer 108).

In some embodiments of the present disclosure, the organic composite protective layer 106 in the contact structure 100 includes a composition having a nitrogen-containing heterocyclic compound or a composition of a cross-linking agent and a coupling agent.

Benzotriazole (BTA) is a widely used copper corrosion inhibitor, but the application of BTA is subject to some restrictions, such as due to poor corrosion inhibition performance of BTA in acidic media, and properties of benzotriazole (BTA) are not well compatible with nanosilver materials (e.g., BTA is not very chemically compatible with nanosilver materials).

In some embodiments, the organic composite protective layer 106 includes a nitrogen-containing heterocyclic compound, which can form a monomolecular adsorption layer on a surface of a metal to achieve a protective effect, such as benzotriazole and imidazoline. A weight ratio of the benzotriazole to the imidazoline may be in a range of from 1:100 to 100:1, such as 1:100 to 1:1, 1:10 to 1:1, 1:5 to 1:1, or 1:3 to 1:1 and so on.

In other embodiments, the organic composite protective layer 106 includes a cross-linking agent and a chelating agent, in which the cross-linking agent is a silane cross-linking agent, a titanate cross-linking agent, a multifunctional cross-linking agent, or a combination thereof; the chelating agent is an organic chelating agent, a metal chelating agent, or a combination thereof. The composition composed of the cross-linking agent and the chelating agent forms a monomolecular adsorption layer on a surface of a metal. In some embodiments, a weight ratio of the cross-linking agent to the chelating agent is in a range of from 1:100 to 100:1, such as 1:1 to 10:1, 1:1 to 6:1, 3:1 to 10:1, or 3:1 to 6:1 and so on.

In some embodiments, the organic composite protective layer 106 has a thickness in a range of from about 50 nm to about 100 nm, such as 50, 60, 70, 80, 90, or 100 nm.

In some embodiments, the contact structure of the present disclosure may be widely used where the copper layer and the nanosilver layer are stacked and in contact with each other. For example, please refer to FIG. 3, which shows an element 200 according to other embodiments of the present disclosure. The element 200 includes a contact structure 210. The contact structure 210 includes a substrate 212, a copper layer 214 (in which the copper layer 214 in indirect contact with the nanosilver layer 218 is denoted as 214″), an organic composite protective layer 216, and a nanosilver layer 218. The contact structure 210 may be an intersection or overlap of a touch electrode and a signal transmission line in a touch panel, and the nanosilver layer 218 is the touch electrode, and the copper layer 214 is the signal transmission line. The contact structure 210 enables the signal of the touch electrode to be transmitted to the signal transmission line. Specifically, the contact structure 210 may be located in a peripheral area of the touch panel or adjacent to a boundary area between the peripheral area and a visible area. The organic composite protective layer 216 is located between the copper layer 214″ and the nanosilver layer 218, does not affect the electrical connection between the copper layer 214″ and the nanosilver layer 218, and prevents the copper layer 214″ from discoloration during a photo process by suppressing copper oxidation during a stripping liquid (e.g., Tetramethylammonium hydroxide) treatment.

The contact structure provided by the embodiments of the present disclosure may be applied to display devices, for example, electronic devices with panels such as mobile phones, tablets, wearable electronic devices (e.g., smart bracelets, smart watches, virtual reality devices, etc.), televisions (TVs), monitors, notebooks, e-books, digital photo frames, navigators, or the like. The element 200 and a touch panel 300 (as shown in FIG. 4) of the embodiments of the present disclosure may be assembled with other electronic components to form a device/product, such as a display with touch function. For example, the element 200 and the touch panel 300 may be bonded to a display element (not shown) such as a liquid crystal display element or an organic light emitting diode (OLED) display element, and the element 200 and the touch panel 300 may be bonded with an optical adhesive or other similar adhesives or bonded to an optical film such as a polarizer (e.g., a stretched polarizer or a liquid crystal coating polarizer), an optical retardation film, etc.

The element 200 and the touch panel 300, etc. of the embodiments of the present disclosure may be applied to electronic devices such as portable phones, tablet computers, notebooks, etc., as well as flexible products. The element 200 and the touch panel 300 of the embodiments of the present disclosure can also be used to manufacture wearable devices (e.g., watches, glasses, smart clothes, smart shoes, etc.) and automotive devices (e.g., dashboards, driving recorders, car rearview mirrors, car windows, etc.).

Please refer to FIG. 4, which is a top view of the touch panel 300 in a display device. The touch panel 300 includes a display area 310 and a peripheral area 320. In the display area 310, touch sensing electrodes 312 are formed from a conductive material comprising nanosilver. In the peripheral area 320, signal transmission lines 321 are formed from a copper layer. The peripheral area 320 includes a plurality of overlapping areas 322, where the touch sensing electrode is electrically connected to the signal transmission line for signal transmission. The overlapping area 322 may include the contact structure 210, as shown in FIG. 3.

In some embodiments, in the overlapping area 322, the nanosilver layer covers one side surface and a portion or all of an upper surface of the copper layer of the signal transmission line, in which the organic composite protective layer is disposed between the copper layer and the nanosilver layer.

In some embodiments, the copper layer is formed over the peripheral area 320 on the substrate of the touch panel 300, and the organic composite protective layer is then disposed over the copper layer. After that, the nanosilver layer is formed over the display area 310 and the peripheral area 320 on the substrate, and the nanosilver layer is also formed over the copper layer and the organic composite protective layer in the peripheral area 320. Afterwards, a photo process is performed, including processes such as coating a photoresist layer, exposure, development, and etching. Therefore, a touch sensing electrode pattern is formed in the display area 310, and the plurality of separate signal transmission lines 321 are formed in the peripheral area 320. In the overlapping area 322 treated by etching, the nanosilver layer is located over the copper layer, and the organic composite protective layer is located between the copper layer and the nanosilver layer. In some embodiments, in the peripheral area 320, the nanosilver layer, the organic composite protective layer, and the copper layer have mutually aligned sides (i.e., a common etching surface). Next, a space between the electrode pattern and the signal transmission lines is filled with an insulating material.

In an alternative embodiment, the nanosilver layer is not only formed in the overlapping area 322, but extends to the entire peripheral area 320, and one-time etching is performed thereon and on the copper layer. Accordingly, the signal transmission line in the peripheral area 320 is a composite structure of the nanosilver layer/organic composite protective layer/copper layer. Specifically, FIG. 5A to FIG. 5C may be combined with reference to the description of the following disclosure.

FIG. 5A is a schematic top view of a touch panel according to some embodiments of the present disclosure, and FIG. 5B and FIG. 5C are cross-sectional views taken along the lines A-A and B-B of FIG. 5A, respectively. The touch panel 500 includes a substrate 510, a peripheral lead 520, a mark 540, a first cover C1, a second cover C2, an organic composite protective layer 550 (refer to FIGS. 5B and 5C), and touch sensing electrodes TE. There may be one or more of the aforementioned peripheral leads 520, the marks 540, the first covers C1, the second covers C2, and the touch sensing electrodes TE, and the amount described in the following specific embodiments and that are drawn in the drawings are for illustrative purposes only and do not limit the present disclosure.

Referring to FIG. 5A, the substrate 510 has a display area VA and a peripheral area PA. The peripheral area PA is disposed at a side of the display area VA. For example, the peripheral area PA may be a frame-shaped area arranged around the display area VA (i.e., including right, left, upper, and lower sides), but in other embodiments, the peripheral area PA may be an L-shaped area disposed at left and lower sides of the display area VA. As shown in FIG. 5A, the present embodiment has eight sets of the peripheral leads 520, and the first covers C1 corresponding to the peripheral leads 520 are disposed over the peripheral area PA of the substrate 510. The touch sensing electrode TE is disposed over the display area VA of the substrate 510. The embodiment further has two sets of the marks 540 and the second covers C2 corresponding to the marks 540, which are disposed over the peripheral area PA of the substrate 510. The organic composite protective layer 550 is provided between the first cover C1 and the peripheral lead 520 to avoid oxidation-reduction reaction between the peripheral lead 520 and the first cover C1 in a specific environment (e.g., in the aforementioned stripping liquid). The organic composite protective layer 550 is also provided between the second cover C2 and the mark 540. In addition, the first cover C1 and the second cover C2 are respectively disposed over the peripheral lead 520 and the mark 540, so that upper and lower layers of the materials may be formed on predetermined positions without alignment, so the need to set the alignment error area in the process can be reduced or avoided, thereby reducing a width of the peripheral area PA, thereby achieving narrow frame requirements of the display.

The touch sensing electrode TE of the embodiment is disposed in the display area VA, and the touch sensing electrode TE may be electrically connected to the peripheral lead 520. Specifically, the touch sensing electrode TE may also be a metal nanowire layer including at least metal nanowires, that is, the metal nanowires form the touch sensing electrode TE in the display area VA and the first cover C1 in the peripheral area PA, and the thickness/characteristics of the monomolecular layer formed from the organic composite protective layer 550 does not affect the electrical conduction between the metal layer and the metal nanowire layer, so the touch sensing electrode TE may be electrically connected for signal transmission through the contacts between the first cover C1, the organic composite protective layer 550, and the peripheral lead 520. The metal nanowires also form the second cover C2 in the peripheral area PA, which is disposed over the mark 540. The mark 540 may be widely interpreted as a pattern with non-electrical functions, but is not limited thereto. In some embodiments of the present disclosure, the peripheral lead 520 and the mark 540 may be made of the same metal layer (i.e., the two are the same metal material). The touch sensing electrode TE, the first cover C1, and the second cover C2 may be made of the same metal nanowire layer.

In this embodiment, the mark 540 is disposed in a bonding area BA of the peripheral area PA, which is a docking alignment mark, that is, in a step (i.e., the bonding step) of connecting an external circuit board such as a flexible circuit board (not shown) to the touch panel 500, a mark is used to align the flexible circuit board (not shown) with the touch panel 500. However, the present disclosure does not limit the placement position or function of the mark 540. For example, the mark 540 may be any check mark, pattern, or label required in the manufacturing processes, which is within the protection scope of the present disclosure. The mark 540 may be any possible shape, such as circular, quadrilateral, cross-shaped, L-shaped, T-shaped, etc., and the organic composite protective layer 550 has substantially the same shape as the mark 540.

As shown in FIG. 5B and FIG. 5C, in the peripheral area PA, there is a non-conductive area 536 between the adjacent peripheral leads 520 to electrically isolate the adjacent peripheral leads 520 from each other to avoid short circuits. In this embodiment, the non-conductive area 536 is a gap to isolate the adjacent peripheral leads 520. In the patterning step, the above-mentioned gap may be made by an etching method, so a sidewall of the peripheral lead 520, a sidewall of the organic composite protective layer 550, and a sidewall of the first cover C1 are a common etching surface and aligned with each other. That is, the three are formed in the same etching step. Similarly, a sidewall of the mark 540, a sidewall of the organic composite protective layer 550, and a sidewall of the second cover C2 are a common etching surface and aligned with each other. Furthermore, the peripheral leads 520, the organic composite protective layer 550, and the first cover C1 have the same or similar patterns and dimensions, such as long and straight patterns with the same or similar widths.

As shown in FIG. 5C, in the display area VA, there is a non-conductive area 536 between the adjacent touch sensing electrodes TE to electrically isolate the adjacent touch sensing electrodes TE from each other to avoid short circuits. In this embodiment, the non-conductive area 536 is a gap to isolate the adjacent touch sensing electrodes TE. In one embodiment, the above-mentioned etching method may be used to form the gap between the adjacent touch sensing electrodes TE. In the embodiment, the touch sensing electrode TE and the first cover C1 may be made of the same layer of the metal nanowire layer (e.g., nanosilver layer), so the metal nanowire layer forms a climbing structure at the junction of the display area VA and the peripheral area PA to form the first cover C1.

In one embodiment, the touch sensing electrode TE adopts a double-layer configuration. In other words, upper and lower surfaces of the substrate are provided with the touch sensing electrodes TE, so the aforementioned peripheral leads 520, the first covers C1, and the organic composite protective layer 550 are formed over the upper and lower surfaces of the substrate.

Please refer to FIGS. 6A to 6C, which illustrate a flowchart of manufacturing a contact structure according to some embodiments of the present disclosure.

As shown in FIG. 6A, a copper layer disposed over a substrate is provided.

In some embodiments, the substrate 602 may be a substrate that may be rigid or flexible. The substrate 602 may be transparent or opaque. Suitable rigid substrates include, for example, polycarbonate, acrylic, and the like. Suitable flexible substrates include (but are not limited to): polyesters (e.g., polyethylene terephthalate (PET), polyethylene naphthalate, and polycarbonate), polyolefins (e.g., linear, with branched and cyclic polyolefins), polyethylene (e.g., polyvinyl chloride, polyvinylidene chloride, polyvinyl acetal, polystyrene, polyacrylate, and the like), cellulose ester base (e.g., cellulose triacetate and cellulose acetate), polysulfone (e.g., polyether sulfone), polyimide, polysiloxane, or other polymer films.

The copper layer 604 is disposed over the substrate 602. The copper layer 604 may be disposed over the substrate 602 by electroplating, electroless plating, or other deposition methods.

As shown in FIG. 6B, an organic composite protective layer 606 is provided on the copper layer 604. In some embodiments, a protective layer solution may be coated on the copper layer 604. In other embodiments, the structure including the copper layer 604 may be immersed in the protective layer solution. The protective layer solution includes an organic protective composition, organic alcohols, and water. In some embodiments, in the protective layer solution, the organic protective composition is present in an amount of from 0.2 to 20 percent by weight, the organic alcohols are present in an amount of from 0.1 to 10 percent by weight, and the water is present in an amount of from 10 to 90 percent by weight.

In some embodiments, the organic protective composition includes benzotriazole and imidazoline, in which the benzotriazole is present in an amount of from about 0.05 to about 20 percent by weight of the protective layer solution, and the imidazoline is present in an amount of from about 0.05 to about 20 percent by weight of the protective layer solution. A weight ratio of the benzotriazole to the imidazoline is in a range of from 1:100 to 100:1, such as 1:100 to 1:1, 1:10 to 1:1, 1:5 to 1:1, or 1:3 to 1:1 and so on.

In other embodiments, the organic protective composition includes a cross-linking agent and a chelating agent. The cross-linking agent is a silane cross-linking agent (general formula: (R1-O)₂—Si-R2-Y), a titanate cross-linking agent (general formula: R1-O—Ti—(O—X1-R2-Y)ₙ, n=2, 3 . . . ), a multifunctional cross-linking agent (e.g., commercially available products: organic trimethoxysilane cross-linking agent, etc.), in which R1 is a functional group that can undergo a hydrolysis reaction and generate Si—OH, including C₁, OMe (Me is a methyl group), OEt (Et is an ethyl group), OC₂H₄OCH₃, OSiMe, etc., R2 is a hydrogen atom, a methyl group, an ethyl group, a propyl group, a butyl group, a phenyl group, a cyclohexyl group, a vinyl group, a propylene group, a aminopropyl group, an aminopropylaminoethyl group, a mercaptopropyl group or an aniline methyl group, etc.; Y is a non-hydrolyzed functional group, including linear olefin functional groups (mainly vinyl functional groups), and hydrocarbyl groups with functional groups such as C₁, NH₂, SH, N₃, epoxy group, (meth)acryloxy group, isocyanate group, etc. at the end, namely a carbon functional group; X1 may be a carboxyl group, an alkoxy group, a sulfonic acid group, a phosphorus group, etc.

The silane cross-linking agents include, for example, hexamethyldisiloxane, tetra(trimethylsiloxy)silane, 3-glycidoxypropyl trimethoxysilane, or a combination thereof.

The titanate cross-linking agents include, for example, triisostearoyl isopropoxy titanate (TTS), chelating phosphate titanium coupling agent, di(octyl pyrophosphate) glycolic acid titanate, di(dioctyl phosphate) ethylene di(alcohol) titanate, or a combination thereof.

The chelating agent is an organic chelating agent, a metal chelating agent, or a combination thereof. The chelating agent may be one or more mixtures of ethylenediaminetetraacetic acid (EDTA), ethylenediamine, potassium sodium tartrate, etc.

In some embodiments, the cross-linking agent is present in an amount of from about 0.05 to about 20 percent by weight of the protective layer solution, and the chelating agent is present in an amount of from about 0.05 to about 20 percent by weight of the protective layer solution. A weight ratio of the cross-linking agent to the chelating agent is in a range of from 1:100 to 100:1, for example, 1:1 to 10:1, or 1:1 to 6:1, or 3:1 to 10:1, or 3:1 to 6:1, etc.

In some embodiments, the alcohol is a single component such as propanol, trimethylbutanol, dipentaerythritol, diacetone alcohol, and ethylene glycol, or a mixture thereof.

As shown in FIG. 6B, the method further includes forming an organic composite protective layer 606 from the protective layer solution. In some embodiments, it is dried by, for example, blow-drying with an air gun and pre-baked.

As shown in FIG. 6C, a nanosilver layer is provided on the organic composite protective layer 606.

As used herein, “metal nanowires” is a collective term that refers to a collection of metal wires containing multiple element metals, metal alloys, or metal compounds (including metal oxides), that the number of the contained metal nanowires does not affect the scope of protection claimed in this disclosure; and at least one cross-sectional dimension (i.e., the diameter of the cross-section) of a single metal nanowire is less than about 500 nm, preferably less than about 100 nm, and more preferably less than about 50 nm; and the metal nanostructure called “wire” in this disclosure mainly has a high aspect ratio, for example, between about 10 and 100,000. More specifically, the aspect ratio (length:diameter of the cross section) of the metal nanowire may be greater than about 10, preferably greater than about 50, and more preferably greater than about 100; the metal nanowire may be any metal, including (but not limited to) silver, gold, copper, nickel, and gold-plated silver. Other terms, such as silk, fiber, tube, etc., if they have the same size and high aspect ratio as mentioned above, are also covered by this application. In some embodiments, the nanosilver layer 608 is prepared by coating a coating composition including a nanosilver structure. To form the coating composition, the silver nanowires are usually dispersed to form a silver nanowire ink/dispersion for the coating process. It should be understood that any suitable liquid that forms a stable silver nanowire dispersion may be used as described herein. Preferably, the silver nanowire is dispersed in water, alcohol, ketone, ether, hydrocarbon, or aromatic solvent (benzene, toluene, xylene, etc.). More preferably, the liquid is volatile, and a boiling point of the liquid is not greater than 200° C., not greater than 150° C., or not greater than 100° C. After a curing/drying step, the solvent and other substances in the slurry are volatilized, and the metal nanowires are randomly distributed on the surface of the substrate, and the metal nanowires can be in contact with each other to provide a continuous current path, thereby forming a conductive network.

In addition, a film layer may be coated to form a composite structure with metal nanowires to have certain specific chemical, mechanical, and optical properties, such as providing adhesion between the metal nanowires and the substrate or better physical mechanical strength, so the film layer may also be called a matrix. On the other hand, some specific polymers are used to allow the film layer to provide the metal nanowires with additional surface protection against scratches and abrasion. In this case, the film layer may also be called a hard coat or overcoat, and polyacrylate, epoxy resin, polyurethane, polysilane, polysiloxane, poly(silicon-acrylic acid), etc. are used and can make the metal nanowires have higher surface strength to improve scratch resistance. Furthermore, ultraviolet (UV) stabilizers may be added to the film layer to improve UV resistance of the metal nanowires. However, the foregoing is only to illustrate the possibility of other additional functions/names of the film layer and is not intended to limit the application.

Afterwards, a patterning process may be performed on the device, including pattern exposure, development (e.g., photolithograph processes), and etching, so that the copper layer 604, the nanosilver layer 608, or both form ideal circuit patterns.

The following is a verification of the implementation of the present disclosure in conjunction with comparative examples and experimental examples. After a laminated structure including a copper layer and a nanosilver layer was formed, the laminated structure was immersed in a common stripping liquid in a photolithograph process, such as “tetramethylammonium hydroxide” and whether the copper layer underneath the nanosilver layer changed color was observed. Among them, discoloration phenomenon may be observed through the Lab reflection color mode. Specific experimental results are listed in Table 1 below, and actual images of several groups of experimental examples are selected for illustration.

TABLE 1

| | | | Appearance | |
|---|---|---|---|---|
| | | A:B | after | |
| | Composition | (wt %) | immersing | Δa* value |
| Comparative Example 1 | no protective layer | — | discoloration | 0.70 |
| Comparative Example 2 | benzotriazole (A) and | 2:1 | discoloration | not |
| | imidazoline (B) | | | measured |
| Experimental Example 1 | benzotriazole (A) and | 1:1 | no | 0.02 |
| | imidazoline (B) | | discoloration | |
| Experimental Example 2 | benzotriazole (A) and | 1:2 | no | 0.39 |
| | imidazoline (B) | | discoloration | |
| Experimental Example 3 | benzotriazole (A) and | 1:3 | no | 0.63 |
| | imidazoline (B) | | discoloration | |
| Experimental Example 4 | hexamethyldisiloxane (A) and | 3:1 | no | 0.06 |
| | ethylenediamine (B) | | discoloration | |
| Experimental Example 5 | hexamethyldisiloxane (A) and | 5:1 | no | 0.14 |
| | ethylenediamine (B) | | discoloration | |
| Comparative Example 3 | hexamethyldisiloxane (A) and | 7:1 | discoloration | 0.85 |
| | ethylenediamine (B) | | | |
| Experimental Example 6 | TTS (A) and EDTA (B) | 8:1 | no | 0.35 |
| | | | discoloration | |

### Comparative Example 1

The copper layer was taken, which was divided into a first area and a second area, and the nanosilver layer was placed on the first area of the copper layer and directly in contact with the copper layer.

FIGS. 7A to 7C are images of Comparative Example 1 after immersion in the tetramethylammonium hydroxide solution for 5 minutes, 10 minutes, and 15 minutes, respectively. As shown in Comparative Example 1, the portion (the first area, on the left side of the figure) of the nanosilver-clad copper layer had obvious discoloration after immersion in the tetramethylammonium hydroxide solution for 5 minutes, and the color thereof was different from that of the second area (on the right side in the figure). After the cooper layer is immersed in the tetramethylammonium hydroxide solution for 10 minutes, the discoloration of the first area of the copper layer became more obvious. After immersion in the tetramethylammonium hydroxide solution for 15 minutes, the first area of the copper layer even turned brown. Please refer to Table 1. In this application, the immersed copper layer was subjected to optical analysis. Under the condition that the protective layer was not added in Comparative Example 1, the Lab reflection color mode was used for quantitative analysis, and the color change of the copper layer was analyzed with the index a*. As shown in Table 1, under the condition of Comparative Example 1, the amount of change in a* (e.g., Δa*) was 0.7. According to this, in the present application, Δa* value not greater than 0.7 can be used as a quantitative indicator of no discoloration/color difference of copper.

### Comparative Example 2

The copper layer was taken, which was divided into a first area and a second area. The copper layer was immersed in a protective layer solution, and an organic protective composition in the protective layer solution was benzotriazole and imidazole with a weight ratio of 2:1. The copper layer was then taken out and dried using an air gun and pre-baked. Next, a nanosilver layer was coated on the first area of the protective layer on the treated copper layer.

FIGS. 8A to 8C are images of Comparative Example 2 after immersion in the tetramethylammonium hydroxide solution for 5 minutes, 10 minutes, and 15 minutes, respectively. As shown in Comparative Example 2, the portion (the first area, on the left side of the figure) of the nanosilver-clad copper layer was slightly discolored after immersion in the tetramethylammonium hydroxide solution for 5 minutes, and the color thereof was slightly different from that of the second area (on the right side in the figure). After immersion in the tetramethylammonium hydroxide solution for 10 minutes, the discoloration of the first area of the copper layer became obvious, and there was a more obvious color difference from the second area. After immersion in the tetramethylammonium hydroxide solution for 15 minutes, the discoloration of the first area of the copper layer was more obvious. Since the discoloration of the copper of Comparative Example 2 was observed by naked eyes, a* was not measured.

### Experimental Example 2

The copper layer was taken, which was divided into a first area and a second area. The copper layer was immersed in a protective layer solution, and an organic protective composition in the protective layer solution was benzotriazole and imidazole with a weight ratio of 1:2. The copper layer was then taken out and dried using an air gun and pre-baked. Next, a nanosilver layer was coated on the first area of the protective layer on the treated copper layer.

FIGS. 9A to 9C are images of Experimental Example 2 after immersion in the tetramethylammonium hydroxide solution for 5 minutes, 10 minutes, and 15 minutes, respectively. As shown in Experimental Example 2, the portion (the first area, on the left side of the figure) of the nanosilver-clad copper layer immersed in the tetramethylammonium hydroxide solution for 5 minutes, 10 minutes, and 15 minutes had no obvious discoloration, and there was no obvious color difference between the portion and the second area of the copper layer. Experimental Example 1, Experimental Example 2, Experimental Example 3 (see Table 1), and Comparative example 2 were analyzed, and the protective layer of the composite formulation composed of benzotriazole and imidazoline with a proportion (e.g., as percent by weight) of the benzotriazole less than or equal to that of imidazoline could exhibit the better anti-discolor effect. However, as the proportion of imidazoline increased, copper began to discolor. The Δa* values in Table 1 also approached 0.7 as the proportion of imidazoline increased. Therefore, this application suggests that the weight ratio of benzotriazole to imidazoline in the range of 1:1 to 1:3 has a better effect.

### Experimental Example 5

The copper layer was taken, which was divided into a first area and a second area. The copper layer was immersed in a protective layer solution, and an organic protective composition in the protective layer solution was benzotriazole and imidazole with a weight ratio of 5:1. The copper layer was then taken out and dried using an air gun and pre-baked. Next, a nanosilver layer was coated on the first area of the protective layer on the treated copper layer.

FIGS. 10A to 10C are images of Experimental Example 5 after immersion in the tetramethylammonium hydroxide solution for 5 minutes, 10 minutes, and 15 minutes, respectively. As shown in Experimental Example 5, the portion (the first area) of the nanosilver-clad copper layer did not exhibit any obvious discoloration after immersion in the tetramethylammonium hydroxide solution for 5 minutes, 10 minutes, and 15 minutes. There was no obvious color difference between the portion and the second area of the copper layer. As shown in Table 1, under the condition of Experimental Example 5, the amount of change in a* was 0.14. Experimental Example 4 and Experimental Example 5 (see Table 1) were analyzed, and the protective layer of the composite formulation composed of hexamethyldisiloxane and ethylenediamine with a proportion (e.g., as percent by weight) of the hexamethyldisiloxane greater than that of ethylenediamine could exhibit the better anti-discolor effect. However, as the proportion of hexamethyldisiloxane to ethylenediamine was adjusted to 7:1, copper started to appear discoloration (i.e., the color of cooper layer is changed). As shown in Comparative Example 3 in Table 1, the measured 4a* value exceeded 0.7. Therefore, this application believes that the weight ratio of hexamethyldisiloxane to ethylenediamine in the range of 3:1 to 6:1 has a better effect.

From the above FIGS. 9A to 9C and FIGS. 10A to 10C, it may be seen that in the stacked structure of the copper layer and the nanosilver layer, the organic composite protective layer can provide the significant anti-oxidation effect when treated with the stripping liquid, so that the nanosilver layer-clad copper layer will not be oxidized and discolored.

Experimental Example 6 in Table 1 was an implementation aspect of a composite formulation of another cross-linking agent and another chelating agent. In Experimental Example 6, the cross-linking agent was triisostearoyl isopropoxy titanate (TTS), and the chelating agent was ethylenediaminetetraacetic acid (EDTA), and the weight ratio thereof was 8:1. After the cooper layer was immersed in tetramethylammonium hydroxide, the Δa* value measured was 0.35. Therefore, the protective layer of Experimental Example 6 also provides a significant anti-oxidation effect, so that the nanosilver layer-clad copper layer will not be oxidized and discolored.

The embodiments of the present disclosure can solve the issue of copper discoloration that occurs after the photo process is performed on the contact structure, so that the device including the contact structure may be produced using the photo process. The manufacturing method using the photo process to manufacture electronic devices containing conductive film layers can provide better time efficiency and reduce production costs.

Although the content of the present disclosure has been disclosed in the above manner, it is not used to limit the content of the present disclosure. Anyone who is familiar with this technique can make various changes and modifications without departing from the spirit and scope of the present disclosure. Therefore, the protection scope of this disclosure shall be subject to those defined by the attached patent application scope.

What is claimed is:

1. A contact structure, comprising:
a substrate;
a copper layer disposed over the substrate;
an organic composite protective layer disposed over the copper layer to mitigate oxidation of the copper layer, wherein the organic composite protective layer forms a monomolecular adsorption layer over a surface of the copper layer; and
a nanosilver layer disposed over the organic composite protective layer.

2. The contact structure of claim 1, wherein the organic composite protective layer comprises a composition having a nitrogen-containing heterocyclic compound, or a composition of a cross-linking agent and a coupling agent.

3. The contact structure of claim 1, wherein the organic composite protective layer comprises benzotriazole and imidazoline.

4. The contact structure of claim 3, wherein a weight ratio of the benzotriazole to the imidazoline is in a range of from 1:100 to 100:1.

5. The contact structure of claim 3, wherein a weight ratio of the benzotriazole to the imidazoline is in a range of from 1:1 to 1:3.

6. The contact structure of claim 1, wherein the organic composite protective layer comprises:
a cross-linking agent, which is a silane cross-linking agent, a titanate cross-linking agent, a multifunctional cross-linking agent, or a combination thereof; and
a chelating agent, which is an organic chelating agent, a metal chelating agent, or a combination thereof.

7. The contact structure of claim 6, wherein a weight ratio of the cross-linking agent to the chelating agent is in a range of from 1:100 to 100:1.

8. The contact structure of claim 6, wherein the cross-linking agent is hexamethyldisiloxane, and the chelating agent is ethylenediamine.

9. The contact structure of claim 8, wherein a weight ratio of the hexamethyldisiloxane to the ethylenediamine is in a range of from 3:1 to 6:1.

10. The contact structure of claim 6, wherein the cross-linking agent is triisostearoyl isopropoxy titanate (TTS), and the chelating agent is ethylenediaminetetraacetic acid (EDTA).

11. The contact structure of claim 1, wherein the organic composite protective layer has a thickness in a range of from about 50 nm to about 100 nm.

12. The contact structure of claim 1, wherein a Δa* value measured after the contact structure is immersed in a stripping liquid is not greater than 0.7.

13. An electronic device comprising the contact structure of claim 1.

14. The electronic device of claim 13, wherein a Δa* value measured after the contact structure is immersed in a stripping liquid is not greater than 0.7.

15. A method of manufacturing a contact structure, comprising:
providing a copper layer disposed over a substrate;
coating a protective layer solution on the copper layer, the protective layer solution comprising:
an organic protective composition, present in an amount of from about 0.1 to about 10 percent by weight of the protective layer solution;
organic alcohols, present in an amount of from about 0.1 to about 10 percent by weight of the protective layer solution; and
water, present in an amount of from about 10 to about 90 percent by weight of the protective layer solution;
forming an organic composite protective layer from the protective layer solution; and
disposing a nanosilver layer over the organic composite protective layer.

16. The method of manufacturing a contact structure of claim 15, wherein the organic protective composition comprises a composition having a nitrogen-containing heterocycle compound, or a composition of a cross-linking agent and a coupling agent.

17. The method of manufacturing the contact structure of claim 16, wherein the organic protective composition comprises:
benzotriazole, present in an amount of from about 0.1 to about 10 percent by weight of the protective layer solution; and
imidazoline, present in an amount of from about 0.1 to about 10 percent by weight of the protective layer solution.

18. The method of manufacturing the contact structure of claim 17, wherein the organic protective composition comprises:
a cross-linking agent, comprising a silane cross-linking agent, a titanate cross-linking agent, a multifunctional cross-linking agent, or a combination thereof, and a ratio of the cross-linking agent in the protective layer solution being in a range of from about 0.05 to about 20 percent by weight; and
a chelating agent, comprising an organic chelating agent, a metal chelating agent, or a combination thereof, and a ratio of the chelating agent in the protective layer solution being in a range of from about 0.05 to about 20 percent by weight.

19. The method of manufacturing the contact structure of claim 15, further comprising: etching the copper layer, the organic composite protective layer, and the nanosilver layer during a patterning process.

20. The method of manufacturing the contact structure of claim 19, wherein after the patterning process, one side of the copper layer, one side of the organic composite protective layer, and one side of the nanosilver layer are aligned with each other.
